(19) United States
(12) Patent Application Publication
(10) Pub. No.: US 2026/0324378 A1
(43) Pub. Date: Oct. 15, 2026

(54) METHOD OF FORMING INTERCONNECT STRUCTURES

(71) Applicant: AVIENT CORPORATION, Avon Lake, OH (US)

(72) Inventors: Vinod PURAYATH, Avon Lake, OH (US); Jian ZHOU, Avon, OH (US); Kenta OHAMA, Tokyo (JP)

(21) Appl. No.: 19/104,563

(22) PCT Filed: Aug. 17, 2023
(86) PCT No.: PCT/US2023/072431

§ 371 Date: Feb. 18, 2025

Related U.S. Application Data
(60) Provisional application No. 63/399,551, filed on Aug. 19, 2022.

(51) Int. Cl. H10W 20/00

(52) U.S. Cl. CPC H10W 20/056; H10W 20/033; H10W 20/043; H10W 20/0526; H10W 20/062; H10W 20/065; H10W 20/067

(57) ABSTRACT

Methods of forming an interconnect structure include providing a polymer solution, providing a dielectric material, spin coating the polymer solution on the dielectric material to form a dispersion in the trench of the electrically conductive composition within the sacrificial polymer, baking the dielectric material such that the sacrificial polymer is removed to form an exposed surface of the electrically conductive composition, sputtering a metal seeding layer to the exposed surface of the electrically conductive composition, electroplating a layer of a copper composition to the metal seeding layer, and performing a chemical mechanical polishing to the layer of a copper composition. The polymer solution includes an electrically conductive composition including at least one of graphene nanosheets and reduced graphene oxide nanosheets, a sacrificial polymer, and a solvent. The dielectric material includes a trench formed into a surface of the dielectric material.

### CLAIM OF PRIORITY

This application claims the benefit of U.S. Provisional Patent Application Ser. No. 63/399,551 bearing Attorney Docket Number 1202216 and filed on Aug. 19, 2022, which is hereby incorporated by reference in its entirety.

### TECHNICAL FIELD

Embodiments of the present disclosure are generally related to interconnect structures and methods of forming interconnect structures.

### BACKGROUND

The continuous downward scaling in integrated circuit (IC) technologies improves transistor performance by increasing switching speed and reducing power consumption. However, size reduction may also degrade electrical performance and reliability due to reduction in interconnect linewidth. Moreover, copper is widely used in interconnect structures. The downward scaling may cause electromigration issues. In particular, when the copper-based interconnect lines are heated up due to their electrical resistance and the high current density being carried through, copper atoms therein may migrate within the interconnect trenches and at the interfaces, which may eventually cause the failure of the interconnect lines (e.g., open circuits or short circuits). Furthermore, conventional processes to form interconnect structures, such as chemical vapor deposition (CVD), may be time-consuming and expensive.

Accordingly, a continual need exists for new and more cost-effective processes of forming an interconnect structure that mitigate electromigration issues of copper based interconnect structures while improving reliability and performance of the integrated circuit chips.

### SUMMARY

Embodiments of the present disclosure are directed to methods of forming interconnect structures including a polymer solution comprising at least one of graphene nanosheets and reduced graphene oxide (rGO) nanosheets and a sacrificial polymer and interconnect structures prepared using a polymer solution comprising at least one of graphene nanosheets and reduced graphene oxide (rGO) nanosheets and a sacrificial polymer The interconnect structures may reduce tthe occurrence of interconnect line failure and improve reliability and performance of the integrated circuit chips. The interconnect structures may have better reliability and/or lower electrical resistance than the copper-only interconnect structures.

According to one or more embodiments, a method of forming the interconnect structure is provided. The method comprises providing a polymer solution, providing a dielectric material, spin coating the polymer solution on the dielectric material to form a dispersion in the trench of the electrically conductive composition within the sacrificial polymer, baking the dielectric material such that the sacrificial polymer is removed to form an exposed surface of the electrically conductive composition, optionally reducing the rGO nanosheets to the graphene nanosheets through an annealing step where the rGO nanosheets included in the electrically conductive composition are reduced to graphene nanosheets, sputtering a metal seeding layer to the exposed surface of the electrically conductive composition, electroplating a layer of a copper composition to the metal seeding layer, and performing a chemical mechanical polishing to the layer of a copper composition. The polymer solution comprises an electrically conductive composition comprising at least one of graphene nanosheets and rGO nanosheets, a sacrificial polymer, and a solvent. The dielectric material includes a trench formed into a surface of the dielectric material.

Additional features and advantages of the embodiments described herein will be set forth in the detailed description which follows, and in part will be readily apparent to those skilled in the art from that description or recognized by practicing the embodiments described herein, including the detailed description, which follows and the claims.

### BRIEF DESCRIPTION OF THE DRAWINGS

The following detailed description of specific embodiments of the present disclosure can be best understood when read in conjunction with the following drawings, where like structure is indicated with like reference numerals and in which:

FIG. 1 depicts a flowchart for a method of forming an interconnect structure, according to one or more embodiments shown and described in this disclosure.

FIG. 2A is a cross-sectional view of a step of forming an interconnect structure including at least one of graphene nanosheets and rGO nanosheets and the interconnect structure having a trench, according to one or more embodiments shown and described herein;

FIG. 2B is a cross-sectional view of another step of forming an interconnect structure including at least one of graphene nanosheets and rGO nanosheets and the interconnect structure having a trench, according to one or more embodiments shown and described herein;

FIG. 2C is a cross-sectional view of another step of forming an interconnect structure including at least one of graphene nanosheets and rGO nanosheets and the interconnect structure having a trench, according to one or more embodiments shown and described herein;

FIG. 2D is a cross-sectional view of another step of forming an interconnect structure including at least one of graphene nanosheets and rGO nanosheets and the interconnect structure having a trench, according to one or more embodiments shown and described herein;

FIG. 2E is a cross-sectional view of another step of forming an interconnect structure including at least one of graphene nanosheets and rGO nanosheets and the interconnect structure having a trench, according to one or more embodiments shown and described herein;

FIG. 2F is a cross-sectional view of another step of forming an interconnect structure including at least one of graphene nanosheets and rGO nanosheets and the interconnect structure having a trench, according to one or more embodiments shown and described herein;

FIG. 2G is a cross-sectional view of another step of forming an interconnect structure including at least one of graphene nanosheets and rGO nanosheets and the interconnect structure having a trench, according to one or more embodiments shown and described herein;

FIG. 3A is a cross-sectional view of a step of forming an interconnect structure including at least one of graphene nanosheets and rGO nanosheets and the interconnect structure having a trench and a via, according to another embodiment shown and described herein;

FIG. 3B is a cross-sectional view of another step of forming an interconnect structure including at least one of graphene nanosheets and rGO nanosheets and the interconnect structure having a trench and a via, according to another embodiment shown and described herein;

FIG. 3C is a cross-sectional view of another step of forming an interconnect structure including at least one of graphene nanosheets and rGO nanosheets and the interconnect structure having a trench and a via, according to another embodiment shown and described herein;

FIG. 3D is a cross-sectional view of another step of forming an interconnect structure including at least one of graphene nanosheets and rGO nanosheets and the interconnect structure having a trench and a via, according to another embodiment shown and described herein;

FIG. 3E is a cross-sectional view of another step of forming an interconnect structure including at least one of graphene nanosheets and rGO nanosheets and the interconnect structure having a trench and a via, according to another embodiment shown and described herein;

FIG. 3F is a cross-sectional view of another step of forming an interconnect structure including at least one of graphene nanosheets and rGO nanosheets and the interconnect structure having a trench and a via, according to another embodiment shown and described herein;

FIG. 3G is a cross-sectional view of another step of forming an interconnect structure including at least one of graphene nanosheets and rGO nanosheets and the interconnect structure having a trench and a via, according to another embodiment shown and described herein;

FIG. 4A is a cross-sectional view of a step of forming an interconnect structure including at least one of graphene nanosheets and rGO nanosheets and metal nanoparticles and the interconnect structure having a trench, according to another embodiment shown and described herein;

FIG. 4B is a cross-sectional view of another step of forming an interconnect structure including at least one of graphene nanosheets and rGO nanosheets and metal nanoparticles and the interconnect structure having a trench and a via, according to another embodiment shown and described herein;

FIG. 4C is a cross-sectional view of another step of forming an interconnect structure including at least one of graphene nanosheets and rGO nanosheets and metal nanoparticles and the interconnect structure having a trench, according to another embodiment shown and described herein;

FIG. 4D is a cross-sectional view of another step of forming an interconnect structure including at least one of graphene nanosheets and rGO nanosheets and metal nanoparticles and the interconnect structure having a trench, according to another embodiment shown and described herein;

FIG. 4E is a cross-sectional view of another step of forming an interconnect structure including at least one of graphene nanosheets and rGO nanosheets and metal nanoparticles and the interconnect structure having a trench, according to another embodiment shown and described herein;

FIG. 4F is a cross-sectional view of another step of forming an interconnect structure including at least one of graphene nanosheets and rGO nanosheets and metal nanoparticles and the interconnect structure having a trench, according to another embodiment shown and described herein;

FIG. 4G is a cross-sectional view of another step of forming an interconnect structure including at least one of graphene nanosheets and rGO nanosheets and metal nanoparticles and the interconnect structure having a trench, according to another embodiment shown and described herein;

FIG. 5A is a cross-sectional view of a step of forming an interconnect structure including at least one of graphene nanosheets and rGO nanosheets and metal nanoparticles and the interconnect structure having a trench and a via, according to another embodiment shown and described herein;

FIG. 5B is a cross-sectional view of another step of forming an interconnect structure including at least one of graphene nanosheets and rGO nanosheets and metal nanoparticles and the interconnect structure having a trench and a via, according to another embodiment shown and described herein;

FIG. 5C is a cross-sectional view of another step of forming an interconnect structure including at least one of graphene nanosheets and rGO nanosheets and metal nanoparticles and the interconnect structure having a trench and a via, according to another embodiment shown and described herein;

FIG. 5D is a cross-sectional view of another step of forming an interconnect structure including at least one of graphene nanosheets and rGO nanosheets and metal nanoparticles and the interconnect structure having a trench and a via, according to another embodiment shown and described herein;

FIG. 5E is a cross-sectional view of another step of forming an interconnect structure including at least one of graphene nanosheets and rGO nanosheets and metal nanoparticles and the interconnect structure having a trench and a via, according to another embodiment shown and described herein;

FIG. 5F is a cross-sectional view of another step of forming an interconnect structure including at least one of graphene nanosheets and rGO nanosheets and metal nanoparticles and the interconnect structure having a trench and a via, according to another embodiment shown and described herein;

FIG. 5G is a cross-sectional view of another step of forming an interconnect structure including at least one of graphene nanosheets and rGO nanosheets and metal nanoparticles and the interconnect structure having a trench and a via, according to another embodiment shown and described herein;

FIG. 6A is a cross-sectional view of a step of forming an interconnect structure including at least one of graphene nanosheets and rGO nanosheets and metal nanoparticles and the interconnect structure having a trench, according to another embodiment shown and described herein;

FIG. 6B is a cross-sectional view of another step of forming an interconnect structure including at least one of graphene nanosheets and rGO nanosheets and metal nanoparticles and the interconnect structure having a trench, according to another embodiment shown and described herein;

FIG. 6C is a cross-sectional view of another step of forming an interconnect structure including at least one of graphene nanosheets and rGO nanosheets and metal nanoparticles and the interconnect structure having a trench, according to another embodiment shown and described herein;

FIG. 6D is a cross-sectional view of another step of forming an interconnect structure including at least one of graphene nanosheets and rGO nanosheets and metal nanoparticles and the interconnect structure having a trench, according to another embodiment shown and described herein;

FIG. 6E is a cross-sectional view of another step of forming an interconnect structure including at least one of graphene nanosheets and rGO nanosheets and metal nanoparticles and the interconnect structure having a trench, according to another embodiment shown and described herein;

FIG. 6F is a cross-sectional view of another step of forming an interconnect structure including at least one of graphene nanosheets and rGO nanosheets and metal nanoparticles and the interconnect structure having a trench, according to another embodiment shown and described herein;

FIG. 6G is a cross-sectional view of another step of forming an interconnect structure including at least one of graphene nanosheets and rGO nanosheets and metal nanoparticles and the interconnect structure having a trench, according to another embodiment shown and described herein; and

FIG. 6H is a cross-sectional view of another step of forming an interconnect structure including at least one of graphene nanosheets and rGO nanosheets and metal nanoparticles and the interconnect structure having a trench, according to another embodiment shown and described herein.

Reference will now be made in greater detail to various embodiments of the present disclosure, some embodiments of which are illustrated in the accompanying drawings. Whenever possible, the same reference numerals will be used throughout the drawings to refer to the same or similar parts.

### DETAILED DESCRIPTION

Reference will now be made in detail to various embodiments of methods of forming an interconnect structure, specifically forming an interconnect structure using at least one of graphene nanosheets and reduced graphene oxide (rGO) nanosheets and a sacrificial polymer.

The disclosure should not be construed as limited to the embodiments set forth herein. Rather, these embodiments are provided so that this disclosure will be thorough and complete, and will fully convey the subject matter to those skilled in the art.

### Definitions

Unless otherwise defined, all technical and scientific terms used herein have the same meaning as commonly understood by one of ordinary skill in the art. The terminology used in the disclosure herein is for describing particular embodiments only and is not intended to be limiting.

Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

As used in the specification and the appended claims, the singular forms “a,” “an,” and “the” are intended to include the plural forms as well, unless the context clearly indicates otherwise. Thus, for example, reference to “a” component includes aspects having two or more such components, unless the context clearly indicates otherwise.

The term “interconnect structure,” as described herein, refers to a structure that electrically connects two or more circuit elements, such as transistors.

The term “trench,” as described herein, refers to a deeply etched area in a dielectric material. A trench may be used to build horizontal interconnect lines of a substrate, for example a wafer substrate. A trench layer may be a network of horizontally oriented trenches in a single layer. Once the trench layer is filled with electrically conducting material, the horizontal interconnect lines in that layer may be formed.

The term “via,” as described herein, refers to an opening in the dielectric layer(s) through which a riser passes, or in which the walls are made conductive; an area that provides an electrical pathway (typically a vertical pathway) from one metal layer to the metal layer above or below. The via may connect two trench layers formed in a layering direction or vertical direction of a device.

The term “field area(s),” as described herein, refers to the surface area(s) outside of the areas for interconnect lines (a trench, a via, or both) in the multi-level interconnect structure of an IC chip device. The field area may be a part of the dielectric material.

The terms “dielectric” and “dielectric materials,” as used herein, refer to materials that are electrical insulators between interconnects (trenches and vias). In some embodiments, a dielectric material is a material that has a relative dielectric constant of 50 or less, 40 or less, 30 or less, 20 or less, 10 or less, or even 3 or less.

The term “flake size,” as described herein, refers to the length of the longest lateral axis of the object, such as graphene, as determined by transmission electron microscopy (TEM).

The term “average,” as described herein, refers to the arithmetic mean value, or some other measure of central tendency, of a characteristic dimension.

The term “lateral dimension,” as described herein, refers to a dimension that extends in a direction substantially perpendicular to the thickness direction of a flat object, such as graphene nanosheets.

The term “thickness,” as described herein, refers to smallest distance between two surfaces of the object, such as graphene nanosheets.

The term “width,” as described herein, refers to a characteristic dimension, generally along a substantially horizontal direction, of a feature.

The term “depth,” as described herein, refers to a characteristic dimension, generally along a substantially vertical direction, of a feature.

The term “diameter,” as described herein, refers to a straight line passing from side to side through the center of a feature in the form of sphere or circular disk.

The term “graphene,” as described herein, refers to a single atomic layer of carbon atoms that are tightly bonded in a hexagonal lattice similar to a honeycomb and form sp² hybridization within the lattice. However, graphene material made by exfoliation of graphite typically has multiple single-layer graphene that are stacked together, and the surface of such graphene materials also have various levels of imperfection or defects depending on the exfoliation process. Oxygen-containing groups are commonly present on the surface of such multi-layer graphene materials

The term “graphene nanosheet,” as described herein, refers to graphene in the form of a nano size sheet formed of multiple layers of single-layer graphene that are stacked together. The graphene nanosheets that are used in the present invention have less than 30 layers of graphene (i.e., single-layer graphene), or less than 20 layers, or less than 10 layers of graphene. The lateral dimension of graphene nanosheets is 1000 nm or less, 700 nm or less, 500 nm or less, or 100 nm or less.

The term “nanosheet,” as described herein, refers to a substantially two dimensional structure with thickness in a scale ranging from 1 nm to 100 nm. In embodiments, the width and length dimensions of the nanosheet may be greater than the thickness dimensions.

The term “lateral dimension of graphene nanosheets,” as described herein, refers to the lateral dimension of a hypothetical circular disk having equivalent area of a graphene nanosheet in its lateral dimensions even if the graphene nanosheet has an irregular shape. The graphene nanosheets prepared in the present disclosure may have a distribution of area sizes in their lateral dimensions, which can be measured by transmission electron microscopy (TEM). The area size distribution as measured may be converted to the distribution in the “lateral dimension of graphene nanosheets” using a simple geometry relationship between area and lateral dimension of a circular shape. Such a distribution in the “lateral dimension of graphene nanosheets” may be plotted in a histogram chart that shows frequency count (in %) of each size bin for the entire range of lateral dimensions of the graphene nanosheet material.

The term “D50 of graphene nanosheets,” as described herein, refers to a lateral dimension value below which 50% (in count) of the graphene nanosheet population as measured in their lateral dimension exist in the population. Similarly, the term “D90 of graphene nanosheets,” as described herein, refers to a lateral dimension value below which 90% (in count) of the graphene nanosheet population as measured exist in the population.

The term “reduced graphene oxide nanosheets,” as described herein, refers to graphene oxide having an oxygen content reduced by a reduction process.

The term “lateral dimension of reduced graphene oxide nanosheets,” as described herein, refers to the lateral dimension of a hypothetical circular disk having equivalent area of a reduced graphene oxide nanosheets in its lateral dimensions even if the reduced graphene oxide nanosheets has an irregular shape. The reduced graphene oxide nanosheets prepared in the present disclosure may have a distribution of area sizes in their lateral dimensions, which can be measured by TEM. The area size distribution as measured may be converted to the distribution in the “lateral dimension of reduced graphene oxide nanosheets,” using a simple geometry relationship between area and lateral dimension of a circular shape. Such a distribution in the “lateral dimension of reduced graphene oxide nanosheets” may be plotted in a histogram chart that shows frequency count (in %) of each size bin for the entire range of lateral dimensions of the reduced graphene oxide nanosheets.

The continuous downward scaling in integrated circuit (IC) technologies improves transistor performance by increasing switching speed and reducing power consumption. However, size reduction may have an adverse effect on interconnect structures by degrading electrical performance and reliability. Downward scaling may cause reduction in interconnect linewidth, which may lead to surge in resistance due to increased contributions from grain boundary and surface scattering of electrons in the metal lines. Furthermore, current density inside interconnect structures may also increase due to the reduced linewidth and exceed the current carrying capacity of conventional interconnect metals (e.g., copper and tungsten). This may lead to electromigration issues. In particular, when the copper-based interconnect lines are heated up due to their electrical resistance and the high current density being carried through, copper atoms therein may migrate within the interconnect trenches and at the interfaces, which may eventually cause the failure of the interconnect lines (e.g., open circuits or short circuits). Moreover, conventional methods to form interconnect structures, such as chemical vapor deposition (CVD), may be time-consuming and expensive.

Disclosed herein are methods of producing interconnect structures which mitigate the aforementioned problems. Specifically, by using graphene nanosheets and/or rGO nanosheets to partially or completely replace copper, the interconnect structures produced by the present disclosure may mitigate the electromigration issue of copper as the amount of copper is reduced and graphene nanosheets and/or rGO nanosheets, which have a relatively large lateral dimension as compared to individual copper atoms, are less likely to migrate when a high electronic current passes through the interconnect lines. Further, the sacrificial polymer used in the present disclosure may minimize agglomeration of the graphene nanosheets and/or the rGO nanosheets and improve initial adhesion of the graphene nanosheets and/or the rGO nanosheets, to the dielectric materials having the trenches and vias. Thus, the interconnect structures produced by the present disclosure reduce the failure of the interconnect lines, such as open circuits or short circuits, and improve reliability and performance of the integrated circuit chips.

The methods of producing interconnect structures disclosed herein may generally be described as including a polymer solution comprising at least one of graphene nanosheets and rGO nanosheets and a sacrificial polymer.

### Method A—Electrically Conductive Composition Including at Least One of Graphene Nanosheets and rGO Nanosheets

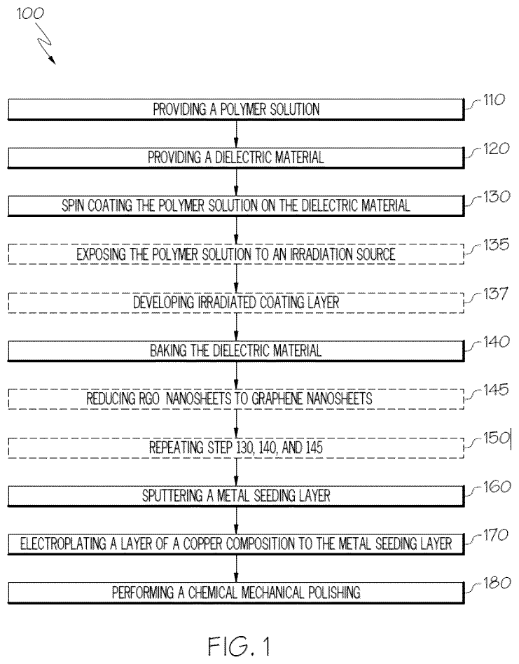

Referring now to FIG. 1, a method of forming an interconnect structure is shown at 100. The method 100 begins at step 110 with providing a polymer solution. The polymer solution may comprise an electrically conductive composition, a sacrificial polymer, and a solvent.

The electrically conductive composition may comprise at least one of graphene nanosheets and rGO nanosheets. In some embodiments, the graphene nanosheets and/or the rGO nanosheets may be produced by an exfoliation and simultaneous size reduction process of graphite materials. For example, the graphene nanosheets, and/or the rGO nanosheets may be prepared from an expanded graphite material that was dispersed and exfoliated in a polar solvent. Using expanded graphite as a starting material may help to ensure that the resulting graphene nanosheet has a certain thickness and lateral dimension as defined herein, as the expanded graphite material may be easier to exfoliate than regular graphite material.

Expanded graphite may be formed from expandable graphite after the expansion process (e.g., thermally triggered) takes place. Expandable graphite may be a modified graphite material having a high proportion of intercalated layers. In some embodiments, sulphur or nitrogen compounds may be used as intercalation agents. Under the influence of heat, the layers may separate like an accordion, and the graphite flakes may expand. Depending upon the grade of expandable graphite, expansion may commence at as low as 180 °C and occur suddenly and rapidly. In the case of free expansion, the final volume may be several hundred times greater than the initial volume. The expanded graphite may have significantly less number of graphene layers (e.g., less than 10 times) than the initial expandable graphite material. The expanded graphite may then be subject to further exfoliation and reduction of the lateral dimensions by a liquid-assisted exfoliation that involves ultra-sonication of the dispersion expanded graphene in a selected solvent.

The selected solvent may be a polar liquid solvent with strong electron withdrawing or donating functional groups such as carbonyl groups. The potentially suitable solvents for the liquid-assisted exfoliation include, but are not limited to, cyrene (i.e., dihydrolevoglucosenone), triacetin, butyl lactate, cyclic aliphatic ketones, benzonitrile, N,N-dimethylacetamide, morpholine, N-methyl-2-pyrrolidone (NMP), and dimethylformamide (DMF). The preferred solvent should have a matching surface energy to that of graphene surface and molecular-level electronic interactions between the graphene layers and the solvent molecules. In embodiments, the solvent for the liquid-assisted exfoliation may comprise cyrene (i.e., dihydrolevoglucosenone), as cyrene is non-toxic solvent, waste derived, and fully biodegradable solvent having sustainability benefits. In embodiments, the solvent used for producing the graphene nanosheet dispersion through the liquid-assisted exfoliation of expanded graphite, for example cyrene, may also be included in the polymer solution.

In embodiments, the expandable graphite, as a starting material, may have less than or equal to 100 mesh flake size, less than or equal to 50 mesh flake size, less than or equal to 30 mesh flake size.

The at least one of the graphene nanosheets and the rGO nanosheets may have D50 along their lateral dimensions less than or equal to 700 nanometers (nm) to ensure that the at least one of the graphene nanosheets and the rGO nanosheets are able to fill a trench and/or via. For example, in embodiments, the at least one of the graphene nanosheets and the rGO nanosheets may have D50 along their lateral dimensions less than or equal to 700 nm, less than or equal to 500 nm, less than or equal to 200 nm, or even less than or equal to 100 nm. In embodiments, the at least one of the graphene nanosheets and the rGO nanosheets may have D50 along their lateral dimensions greater than or equal to 5 nm, greater than or equal to 10 nm, greater than or equal to 15 nm, or even greater than or equal to 20 nm. In embodiments, the at least one of the graphene nanosheets and the rGO nanosheets may have D50 from 5 nm to 700 nm, from 5 nm to 500 nm, from 5 nm to 200 nm, from 5 nm to 100 nm, from 10 nm to 700 nm, from 10 nm to 500 nm, from 10 nm to 200 nm, from 10 nm to 100 nm, from 15 nm to 700 nm, from 15 nm to 500 nm, from 15 nm to 200 nm, from 15 nm to 100 nm, from 20 nm to 700 nm, from 20 nm to 500 nm, from 20 nm to 200 nm, or even from 20 nm to 100 nm, or any and all sub-ranges formed from any of these endpoints.

In embodiments, at least one of the graphene nanosheets and the rGO nanosheets may have an average thickness less than or equal to 15 nm, less than or equal to 12.5 nm, or even less than or equal to 10 nm. In embodiments, at least one of the graphene nanosheets and the rGO nanosheets may have an average thickness greater than or equal to 0.1 nm, greater than or equal to 0.2 nm, greater than or equal to 0.3 nm, or greater than or equal to 0.35 nm. In embodiments, at least one of the graphene nanosheets and the rGO nanosheets may have an average thickness from 0.1 nm to 15 nm, from 0.1 nm to 12.5 nm, from 0.1 nm to 10 nm, from 0.2 nm to 15 nm, from 0.2 nm to 12.5 nm, from 0.2 nm to 10 nm, from 0.3 nm to 15 nm, from 0.3 nm to 12.5 nm, from 0.3 nm to 10 nm, from 0.35 nm to 15 nm, from 0.35 nm to 12.5 nm, even from 0.35 nm to 10 nm, or any and all sub-ranges formed from any of these endpoints.

The sacrificial polymer may help stabilize the graphene dispersion by preventing self-agglomeration of graphene nanosheets in the polymer solution.

In embodiments, the sacrificial polymer may be polar. A polar sacrificial polymer may have good adhesion to common silicon based dielectric materials such as silicon, silicon dioxides, silicon carbides, silicon nitrides, or combinations thereof, due to the interaction between polar groups of the sacrificial polymers and polar groups present on the surface of the dielectric materials. Various sacrificial polymers are considered suitable for the present polymer solution. In embodiments, the sacrificial polymers may be selected from the group consisting of polypropylene carbonate (PPC), polymethyl methacrylate (PMMA), poly(phthalaldehyde) including cyclic poly(phthalaldehyde), polylactides, and polyhydroxyalkonoates, and combinations thereof. In embodiments, the sacrificial polymer may not include a cellulose acetate butyrate. In embodiments, the polymer solution may not include a cellulose acetate butyrate.

In embodiments, the polymer solution may include a certain amount of sacrificial polymer to achieve a desired viscosity of the polymer solution for a spin-coating process (e.g., 7 to 55 centipoise).

Various solvents are considered suitable for the present polymer solution. In embodiments, the solvent may be a polar solvent. In embodiments, the solvent may include one or more of cyrene, triacetin, butyl lactate, cyclic aliphatic ketones, benzonitrile, N,N-dimethylacetamide, morpholine, N-methyl-2-pyrrolidone (NMP), dimethylformamide (DMF), and combinations thereof.

In embodiments, the graphene nanosheets are the only conductive fillers dispersed in the polymer solution.

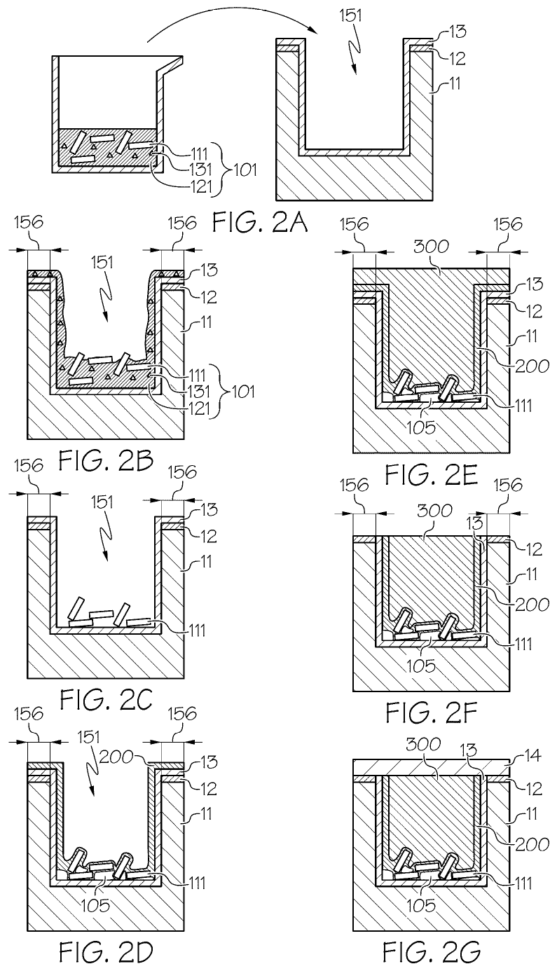

Referring back FIG. 1, the method 100 continues at step 120 where a dielectric material is provided. Referring now to FIG. 2A, dielectric material 11 may include a trench 151 formed into a surface of the dielectric material 11. In some embodiments, a first dielectric passivation layer 12 may be disposed on at least a part of the dielectric material 11. In embodiments, the first dielectric passivation layer 12 may not be disposed on the trench 151. In embodiments, the first dielectric passivation layer 12 may comprise silicon oxide. In embodiments, a barrier layer 13 may be disposed on the first dielectric passivation layer 12 and the trench 151. In some embodiments, the barrier layer 13 may comprise tantalum nitride.

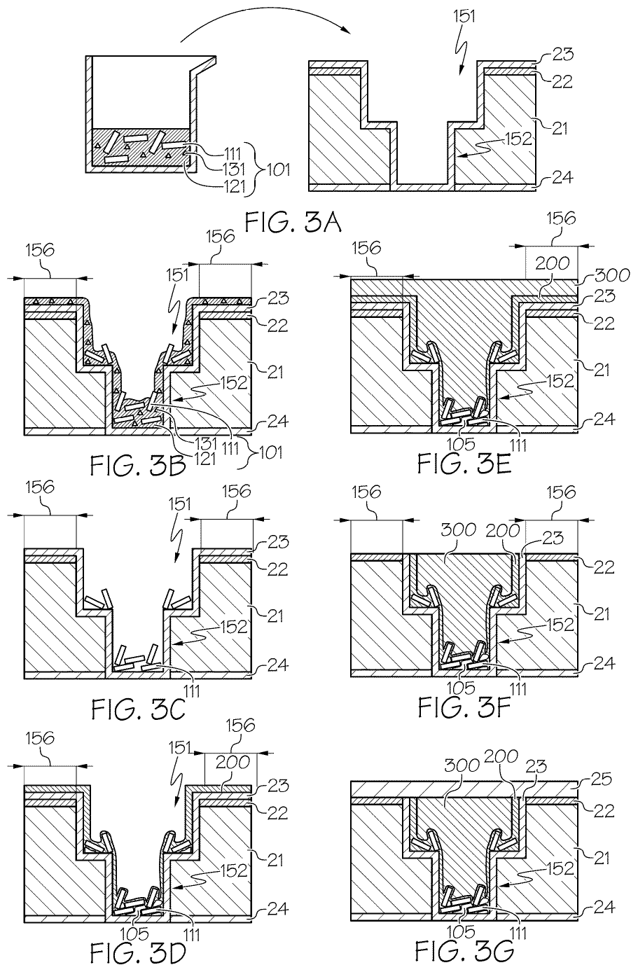

Referring now to FIG. 3A, in alternative embodiments, dielectric material 21 may have a trench 151 and a via 152. The via 152 may be disposed in the trench 151. The dielectric material 21 may be disposed on a first dielectric passivation layer 24. In embodiments, the first dielectric passivation layer 24 may comprise silicon nitride. In some embodiments, a second dielectric passivation layer 22 may be disposed on at least a part of the dielectric material 21. In embodiments, the second dielectric passivation layer 22 may not be disposed on the trench 151 and the via 152. In embodiments, the second dielectric passivation layer 22 may comprise silicon oxide. In embodiments, a barrier layer 23 may be disposed on the second dielectric passivation layer 22, the trench 151, and the via 152. In some embodiments, the barrier layer 23 may comprise tantalum nitride.

In embodiments, each of the trench 151 and the via 152 may have a width less than or equal to 1000 nm, less than or equal to 500 nm, or even less than or equal to 300 nm. In embodiments, each of the trench 151 and the via 152 may have a width greater than or equal to 5 nm, greater than or equal to 10 nm, greater than or equal to 15 nm, or even greater than or equal to 30 nm. In embodiments, each of the trench 151 and the via 152 may have a width from 5 nm to 1000 nm, from 5 nm to 500 nm, from 5 nm to 300 nm, from 10 nm to 1000 nm, from 10 nm to 500 nm, from 10 nm to 300 nm, from 15 nm to 1000 nm, from 15 nm to 500 nm, from 15 nm to 300 nm, from 30 nm to 1000 nm, from 30 nm to 500 nm, or even from 30 nm to 300 nm, or any and all sub-ranges formed from any of these endpoints. With these width ranges, the at least one of the graphene nanosheets and the rGO nanosheets 111 lateral dimensions as described herein may be able to fill in the trench 151 and/or the via 152.

In embodiments, the depth to width aspect ratio of the trench 151 may be greater than or equal to 0.5, greater than or equal to 1.0, or even greater than or equal to 1.5. In embodiments, the depth to width aspect ratio of the trench 151 may be less than or equal to 4.0, less than or equal to 3.5, less than or equal to 3.0, or even less than or equal to 2.5. In embodiments, the depth to width aspect ratio of the trench 151 may be from 0.5 to 4.0, from 1.0 to 4.0, from 1.5 to 4.0, from 0.5 to 3.5, from 1.0 to 3.5, from 1.5 to 3.5, from 0.5 to 3.0, from 1.0 to 3.0, from 1.5 to 3.0, from 0.5 to 2.5, from 1.0 to 2.5, or even from 1.5 to 2.5, or any and all sub-ranges formed from any of these endpoints.

In embodiments, the depth to width aspect ratio of the via 152 may be greater than or equal to 0.5, greater than or equal to 1.0, or even greater than or equal to 1.5. In embodiments, the depth to width aspect ratio of the via 152 may be less than or equal to 4.0, less than or equal to 3.5, less than or equal to 3.0, or even less than or equal to 2.5. In embodiments, the depth to width aspect ratio of the via 152 may be from 0.5 to 4.0, from 1.0 to 4.0, from 1.5 to 4.0, from 0.5 to 3.5, from 1.0 to 3.5, from 1.5 to 3.5, from 0.5 to 3.0, from 1.0 to 3.0, from 1.5 to 3.0, from 0.5 to 2.5, from 1.0 to 2.5, even from 1.5 to 2.5, or any and all sub-ranges formed from any of these endpoints.

Still referring to FIGS. 1, 2A, and 3A, a polymer solution 101 including the at least one of the graphene nanosheets and the rGO nanosheets 111, the solvent 121, and the sacrificial polymer 131 may be provided on the dielectric material 11, 21.

Referring back to FIG. 1 and now to FIGS. 2B and 3B, the method 100 continues at step 130 where the polymer solution 101 on the dielectric material 11, 21 is spin coated to form a dispersion in the trench 151 as shown in FIG. 2B or the trench 151 and the via 152 as shown in FIG. 3B. Spin coating may be faster and consumes less energy than CVD. In some embodiments, the polymer solution 101 on the dielectric material 11, 21 may be spin coated to a wafer substrate having the trenches for interconnect lines and field area 156. The polymer solution 101 may be spin coated to form a polymer solution 101 coating layer on the dielectric material 11, 21. The polymer solution 101 coating layer after step 130 may comprise the sacrificial polymer 131, residual solvent 121, and at least one of the graphene nanosheets and the rGO nanosheets 111. The sacrificial polymer 131 may act as a binder in the polymer solution 101 coating layer. The sacrificial polymer may have a good adhesion to the barrier layer 13 disposed on the wall and bottom of the trench 151, and the field area 156.

Referring back to FIG. 1 and now to FIGS. 2C and 3C, the method 100 continues at step 140 where the dielectric material 11, 21 is baked such that both the residual solvent 121 and the sacrificial polymer 131 of the polymer solution 101 coating layer is removed to form an exposed surface of the electrically conductive composition including the at least one of the graphene nanosheets and the rGO nanosheets 111. The dielectric material 11 may be baked such that the sacrificial polymer 131 and the residual solvent 121 (shown in FIGS. 2B and 3B) are completely removed.

In some embodiments, the dielectric material 11, 21 may be baked under an inert gas. In some embodiments, the dielectric material 11, 21 may be baked at a temperature greater than or equal to 350 ⋅, greater than or equal to 400 ⋅, greater than or equal to 450 ⋅, or even greater than or equal to 500 ⋅. In some embodiments, the dielectric material 11, 21 may be baked at a temperature less than or equal to 1000 ⋅, less than or equal to 950 ⋅, or even less than or equal to 900 ⋅. In embodiments, the dielectric material 11, 21 may be baked at a temperature from 350 ⋅ to 1000 ⋅, from 350 ⋅ to 950 ⋅, from 350 ⋅ to 900 ⋅, from 400 ⋅ to 1000 ⋅, from 400 ⋅ to 950 ⋅, from 400 ⋅ to 900 ⋅, from 450 ⋅ to 1000 ⋅, from 450 ⋅ to 950 ⋅, from 450 ⋅ to 900 ⋅, from 500 ⋅ to 1000 ⋅, from 500 ⋅ to 950 ⋅, or even from 500 ⋅ to 900 ⋅, or any and all sub-ranges formed from any of these endpoints. At these temperature ranges, the sacrificial polymer 131 may be decomposed in step 140. In some embodiments, in step 140, at least 90%, at least 95%, at least 99%, or at least 99.9% of the sacrificial polymer 131 may be decomposed.

Referring back to FIG. 1, in some embodiments, the method 100 may optionally continue at step 145 where the rGO nanosheets are reduced to the graphene nanosheets through an annealing step. In some embodiments, the oxygen content of the rGO nanosheets, which is normally between 10 wt % and 20 wt %, may be reduced to less than or equal to 3 wt % in order to convert rGO to the graphene nanosheets through an annealing step. The reducing step 145 may improve the electrical performance of the electrically conductive composition comprising the rGO nanosheets. In some embodiments, the rGO nanosheets may be converted to the graphene nanosheets through an annealing step in the presence of a reducing agent. The reducing agent may comprise hydrogen.

Referring back to FIG. 1, in some embodiments, the method 100 may optionally continue at step 150 where one or more of steps 130, 140, and 145 may be repeated until the at least one of the graphene nanosheets and the rGO nanosheets fill the depth of the trench 151 and/or the via 152 as shown in FIGS. 2D and 3D. By repeating steps 130, 140, and 145, the amount of the electroplated copper composition may be reduced. In some embodiments, step 130 may be repeated one or more times prior to proceeding to step 140 or step 140 and 145. In some embodiments, steps 130 and 140 may be repeated one or more times. In some embodiments, all of steps 130, 140, and 145 may be repeated one or more times, Referring back to FIG. 1 and now to FIGS. 2D and 3D, the method 100 continues at step 160 where a metal seeding layer 200 is sputtered to the exposed surface of the electrically conductive composition including the at least one of the graphene nanosheets and the rGO nanosheets 111. In some embodiments, the metal seeding layer 200 may be selected from the group consisting of copper, a copper alloy, and both. The metal seeding layer 200 may be sputtered to the at least one of the graphene nanosheets and the rGO nanosheets 111, the barrier layer 13 disposed on the first dielectric passivation layer 12, and the trench 151 as shown in FIG. 2D, or sputtered to the at least one of the graphene nanosheets and the rGO nanosheets 111, the barrier layer 23 disposed on the second dielectric passivation layer 22, the trench 151, and the via 152 as shown in FIG. 3D. In some embodiments, voids 105 may be formed underneath some graphene nanosheets and the rGO nanosheets after step 140. The voids 105 may remain as in FIGS. 2D and 3D and the following steps 170 and 180, and may also be present in the final interconnect structure. This may be because of that the sputtering process (step 160) is a conformal coating process and may not fill those void spaces 105 underneath some graphene nanosheets and the rGO nanosheets.

Referring back to FIG. 1 and now to FIGS. 2E and 3E, the method 100 continues at step 170 where a layer of a copper composition 300 is electroplated to the metal seeding layer 200. In some embodiments, the copper composition 300 may be selected from the group consisting of copper, a predominantly copper alloy, and both. In some embodiments, the copper composition 300 may be copper with greater than 99% purity orgreater than or equal to 99.5% purity. In some embodiments, the predominantly copper alloy may be an alloy having greater than or equal to 90 weight percent (wt %), 95 wt %, 98 wt %, 99 wt %, or 99.5 wt % of copper based on the total weight of the alloy. In step 170, the layer of the copper composition 300 may be electroplated to the metal seeding layer 200 to fill the trench 151. In step 170, at least one of the graphene nanosheets and the rGO nanosheets 111 may be fillers at least partially imbedded in the layer of the copper composition 300. The layer of the copper composition 300 may be electroplated to the metal seeding layer 200 and fill the trench 151 as shown in FIG. 2E or electroplated to the metal seeding layer 200 and fill the trench 151 and the via 152 as shown in FIG. 3E.

Referring back to FIG. 1 and now to FIGS. 2F and 3F, the method 100 continues at step 180 where a chemical mechanical polishing (CMP) is performed to the layer of a copper composition 300. In step 180, at least one of the top layers of the dielectric material 11, 21 may be planarized. In step 180, the excessive layer of a copper composition 300 above the trench 151 level may be polished away. In step 180, a certain depth of the top surface of the dielectric material 11, 21 may be removed in the CMP process until the layer comprising at least one of the graphene nanosheets and the rGO nanosheets 111 left in the field area 156 (as still shown in FIGS. 2C, 2D, 2E, 3C, 3E, and 3F) is removed from the field area 156. The removed depth may be up to 100 nm as needed to remove the remaining layer comprising at least one of the graphene nanosheets and the rGO nanosheets 111 left in the field area 156. In step 180, some of the top layers of the copper composition 300 may be removed from the metal seeding layer 200 and the trench 151 as shown in FIG. 2F or removed from the metal seeding layer 200, the trench 151, and the via 152 as shown in FIG. 3F. The barrier layer 13 disposed on the first dielectric passivation layer 12 may be removed as shown in FIG. 2F. The barrier layer 23 disposed on the second dielectric passivation layer 22 may be removed as shown in FIG. 3F.

In some embodiments, in step 180, a portion of the copper in the layer of a copper composition 300 may be oxidized in the presence of an oxidizing agent. In some embodiments, the oxidizing agent may be selected from the group consisting of H₂O₂ (i.e., hydrogen peroxide), HNO₄, and ferrous salts comprising Fe⁺³ ions. In step 180, a portion of the oxidized copper may be removed. In step 180, a portion of the layer of the copper composition 300 may be oxidized to form an oxidized layer 400 and at least a portion of the oxidized layer 400 may be removed from the layer of the copper composition 300 and the trench 151 as shown in FIG. 2F or removed from the layer of the copper composition 300, the trench 151, and the via 152 as shown in FIG. 3F. The oxidized copper may have lower conductivity than copper. In some embodiments, the oxidized copper may be reduced back to copper in the presence of a reducing agent through an annealing step. The reducing agent may comprise hydrogen.

In some embodiments, another dielectric passivation layer may be provided on the trench to close the trench. In some embodiments, the another dielectric passivation layer may comprise silicon nitride. For example, a second dielectric passivation layer 14 may be provided on the dielectric passivation layer 12, the layer of the copper composition 300, and the trench 151 as shown in FIG. 2G. The third dielectric passivation layer 25 may be provided on the first dielectric passivation layer 22, the layer of the copper composition 300, the trench 151, and the via 152 as shown in FIG. 3G.

### Method B—Electrically Conductive Composition Including Metal Nanoparticles and at Least One of Graphene Nanosheets and rGO Nanosheets

In embodiments, the electrically conductive composition may further comprise metal nanoparticles. During formation of the interconnect structure, metal nanoparticles may form a continuous melt phase directly contacting the conductive barrier layer at the bottom surface and side walls of the trenches and ensure good connection between the barrier layer and the at least one of graphene nanosheets and rGO nanosheets, leading to improved overall conductivity of the interconnect structure. Methods of forming an interconnect structure including a polymer solution having metal nanoparticles are similar to Method A with respect to a polymer solution including at least one of graphene nanosheets and reduced rGO nanosheets, a sacrificial polymer, and a solvent. For example, referring back to FIG. 1, in step 110, a polymer solution is provided. The polymer solution may comprise an electrically conductive composition, a sacrificial polymer, and a solvent. The electrically conductive composition may comprise at least one of graphene nanosheets, reduced graphene oxide (rGO) nanosheets, and metal nanoparticles. The sacrificial polymer and the solvent included in the polymer solution including the metal nanoparticles may be similar to or the same as the sacrificial polymer and the solvent described above with respect to Method A. Various metal nanoparticles are considered suitable for the present electrically conductive composition. In embodiments, the metal nanoparticles may be selected from the group consisting of copper, cobalt, ruthenium, nickel, titanium, aluminum, silver, gold, tungsten, platinum, palladium, and combinations thereof.

In some embodiments, an average diameter of the metal nanoparticles may be smaller than the average lateral dimension of at least one of the graphene nanosheets and the rGO nanosheets. The metal nanoparticle with smaller sizes may go between at least one of the graphene nanosheets and the rGO nanosheets in the polymer coating layer. This may help reduce the chance of self-agglomeration of graphene nanosheets in the process. In embodiments, the metal nanoparticles may have an average diameter less than or equal to 25 nm, less than or equal to 22.5 nm, or even less than or equal to 20 nm. In embodiments, the metal nanoparticles may have an average diameter greater than or equal to 2 nm, greater than or equal to 3 nm, greater than or equal to 4 nm, or even greater than or equal to 5 nm. In embodiments, the metal nanoparticles may have an average diameter from 1 nm to 25 nm, from 1 nm to 22.5 nm, from 1 nm to 20 nm, from 2 nm to 25 nm, from 2 nm to 22.5 nm, from 2 nm to 20 nm, from 3 nm to 25 nm, from 3 nm to 22.5 nm, from 3 nm to 20 nm, from 4 nm to 25 nm, from 4 nm to 22.5 nm, from 4 nm to 20 nm, from 5 nm to 25 nm, from 5 nm to 22.5 nm, or even from 5 nm to 20 nm, or any and all sub-ranges formed from any of these endpoints.

In some embodiments, before the metal nanoparticles are provided in the polymer solution, the metal nanoparticles may be pre-treated by thiolate capping ligands. The thiolate capping ligands may have at least a second polar end group selected from the group consisting of —COOH, —OH, —SH, and combinations thereof. The pre-treatment step may improve the dispersion of metal nanoparticles in the polymer solution. The pre-treatment step may promote a stronger interaction between the metal nanoparticles and at least one of the graphene nanosheets and the rGO nanosheets due to a potential hydrogen bonding between the second polar end group (hydrogen donor) on metal nanoparticles' surface and oxygen containing groups (e.g., carbonyl group as hydrogen receiver) on the surface of at least one of the graphene nanosheets and the rGO nanosheets. The stronger interaction between the metal nanoparticles and at least one of the graphene nanosheets and the rGO nanosheets may prevent self-agglomeration of at least one of the graphene nanosheets and the rGO nanosheets which would reduce the electrical conductivity of the resulting interconnects.

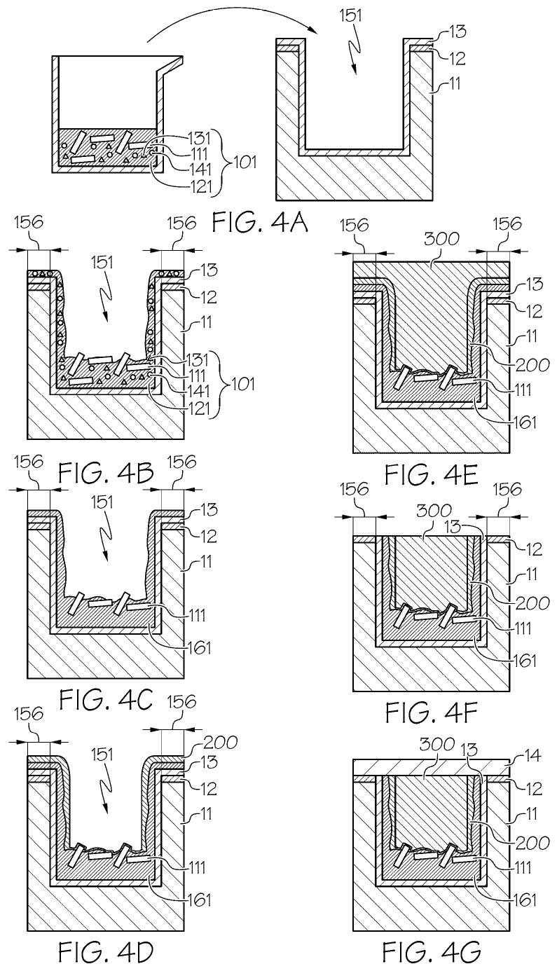

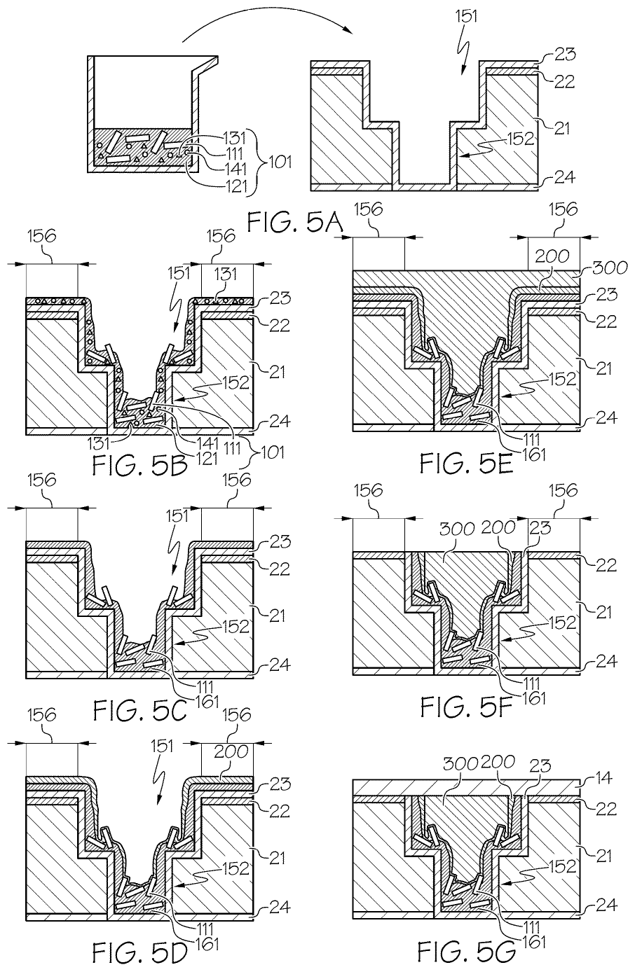

Referring back FIG. 1, the method 100 continues at step 120 where a dielectric material is provided. As shown in FIGS. 4A and 5A, the dielectric material 11, 21 may be the same or similar to the dielectric material shown in FIGS. 2A and 3A with respect to Method A.

Referring back FIG. 1 and now to FIGS. 4B and 5B, the method 100 continues at step 130 where the polymer solution 101 on the dielectric material 11, 21 is spin coated to form a dispersion in the trench 151 as shown in FIG. 4B or the trench 151 and the via 152 as shown in FIG. 5B. The polymer solution 101 including the at least one of the graphene nanosheets and the rGO nanosheets 111, the solvent 121, the sacrificial polymer 131, and the metal nanoparticles 141 may be provided and applied onto the dielectric material 11, 21 in a spin-coating step 130. After the spin-coating step 130, the polymer solution 101 coating layer including the at least one of the graphene nanosheets and the rGO nanosheets 111, the residual solvent 121, the sacrificial polymer 131, and the metal nanoparticles 141 may be present in the trench 151 and the surrounding field area 156 as shown in FIG. 4B, or in the trench 151 and via 152 and the surrounding field area 156 as shown in FIG. 5B.

Referring back to FIG. 1 and now to FIGS. 4C and 5C, the method 100 continues at step 140 where the dielectric material 11, 21 is baked such that the sacrificial polymer 131 and the residual solvent 121 (shown in FIGS. 4B and 5B) may be removed to form an exposed surface of the electrically conductive composition including the at least one of the graphene nanosheets and the rGO nanosheets 111 and the metal nanoparticles 141. Step 140 may further comprise sintering the metal nanoparticles 141. In the sintering step, the metal nanoparticles 141 may be sintered to form a continuous metal phase 161. The sintering step may cause at least one of the graphene nanosheets and the rGO nanosheets 111 to be partially repelled from (i.e., partially embedded in) the continuous metal phase 161, but at least one of the graphene nanosheets and the rGO nanosheets 111 may maintain sufficient contact with the continuous melt phase 161. At least one of the graphene nanosheets and the rGO nanosheets 111 may move to the top portion of the continuous metal phase 161 during the sintering process because graphene has a lighter density than the metal. The continuous melt phase 161 ensures connection between the dielectric material 11, 21 and the at least one of graphene nanosheets and rGO nanosheets 111, leading to improved conductivity.

The metal nanoparticles 141 may have lower melting point than the corresponding bulk metal due to their nanometer sizes. In some embodiments, the metal nanoparticles may have a melting point of greater than or equal to 100 ⋅, greater than or equal to 120 ⋅, greater than or equal to 140 ⋅, greater than or equal to 160 ⋅, greater than or equal to 180 ⋅, or even greater than or equal to 200 ⋅. In some embodiments, the metal nanoparticles 141 may have a melting point of less than or equal to 400 ⋅, less than or equal to 420 ⋅, less than or equal to 440 ⋅, less than or equal to 460 ⋅, less than or equal to 480 ⋅, or even less than or equal to 500 ⋅. In embodiments, the metal nanoparticles 141 may have a melting point of from 100 ⋅ to 400 ⋅, from 100 ⋅ to 420 ⋅, from 100 ⋅ to 440 ⋅, from 100 ⋅ to 460 ⋅, from 100 ⋅ to 480 ⋅, from 100 ⋅ to 500 ⋅, from 120 ⋅ to 400 ⋅, from 120 ⋅ to 420 ⋅, from 120 ⋅ to 440 ⋅, from 120 ⋅ to 460 ⋅, from 120 ⋅ to 480 ⋅, from 120 ⋅ to 500 ⋅, from 140 ⋅ to 400 ⋅, from 140 ⋅ to 420 ⋅, from 140 ⋅ to 440 ⋅, from 140 ⋅ to 460 ⋅, from 140 ⋅ to 480 ⋅, from 140 ⋅ to 500 ⋅, from 160 ⋅ to 400 ⋅, from 160 ⋅ to 420 ⋅, from 160 ⋅ to 440 ⋅, from 160 ⋅ to 460 ⋅, from 160 ⋅ to 480 ⋅, from 160 ⋅ to 500 ⋅, from 180 ⋅ to 400 ⋅, from 180 ⋅ to 420 ⋅, from 180 ⋅ to 440 ⋅, from 180 ⋅ to 460 ⋅, from 180 ⋅ to 480 ⋅, from 180 ⋅ to 500 ⋅, from 200 ⋅ to 400 ⋅, from 200 ⋅ to 420 ⋅, from 200 ⋅ to 440 ⋅, from 200 ⋅ to 460 ⋅, from 200 ⋅ to 480 ⋅, even from 200 ⋅ to 500 ⋅, or any and all sub-ranges formed from any of these endpoints. Referring back to FIG. 1, in some embodiments, the method 100 may optionally continue at step 145 where the rGO nanosheets are reduced to the graphene nanosheets through an annealing step. In some embodiments, the oxygen content of the rGO nanosheets, which is normally between 10 wt % and 20 wt %, may be reduced to less than or equal to 3 wt % in order to convert rGO to the graphene nanosheets through an annealing step. The reducing step 145 may improve the electrical performance of the electrically conductive composition comprising the rGO nanosheets. In some embodiments, the rGO nanosheets may be converted to the graphene nanosheets through an annealing step in the presence of a reducing agent. The reducing agent may comprise hydrogen.

Referring back to FIG. 1, in some embodiments, the method 100 may optional continue at step 150 where the steps 130, 140, and 145 may be repeated until the at least one of the graphene nanosheets and the rGO nanosheets, and the metal nanoparticles 141 fill the depth of the trench 151 and/or the via 152 as shown in FIGS. 4C and 5C. By repeating steps 130, 140, and 145, the amount electroplated copper composition needed may be reduced.

Referring back to FIG. 1 and now to FIGS. 4D and 5D, the method 100 continues at step 160 where a metal seeding layer 200 is sputtered to the exposed surface of the electrically conductive composition including the graphene nanosheets and the rGO nanosheets 111 and the continuous metal phase 161. In some embodiments, the metal seeding layer 200 may be sputtered to cover the at least one of the graphene nanosheets and the rGO nanosheets 111, the exposed surface of continuous metal phase 161, or both. In some embodiments, the metal seeding layer 200 may be selected from the group consisting of copper, copper alloy, and both. The metal seeding layer 200 may be sputtered to the at least one of the graphene nanosheets and the rGO nanosheets 111, the continuous metal phase 161, the barrier layer 13 disposed on the dielectric passivation layer 12, and the trench 151 as shown in FIG. 4D or sputtered to the at least one of the graphene nanosheets and the rGO nanosheets 111, the continuous metal phase 161, the barrier layer 23 disposed on the second dielectric passivation layer 22, the trench 151, and the via 152 as shown in FIG. 5D. The voids 105 shown in FIGS. 2D and 3D may not be present in FIGS. 4D and 5D because the continuous metal phase 161 may be able to fill the voids that are otherwise present between graphene nanosheets and rGO nanosheets in the absence of the metal nanoparticles during the baking step. The absence of voids in the final interconnect may increase the electrical contact resistance of the electrically conductive composition deposited in the interconnect trenches and vias.

Referring back to FIG. 1 and now to FIGS. 4E and 5E, the method 100 continues at step 170 where a layer of a copper composition 300 is electroplated to the metal seeding layer 200. As shown in FIGS. 4E and 5E, step 170 of Method B may be the same as or similar to step 170 shown in FIGS. 2E and 3E and described above with respect to Method A.

Referring back to FIG. 1 and now to FIGS. 4F and 5F, the method 100 continues at step 180 where a chemical mechanical polishing is performed to the layer of a copper composition 300. As shown in FIGS. 4F and 5F, step 180 of Method B may be the same as or similar to step 180 shown in FIGS. 2F and 3F and described above with respect to Method A.

Still Referring now to FIGS. 4G and 5G, another dielectric passivation layer 14, 25 may be provided in the same or a similar manner as shown in FIGS. 2G and 3G and described above with respect to Method A.

### Method C—Polymer Solution Including Photo-Intiator and Crosslinking Agent

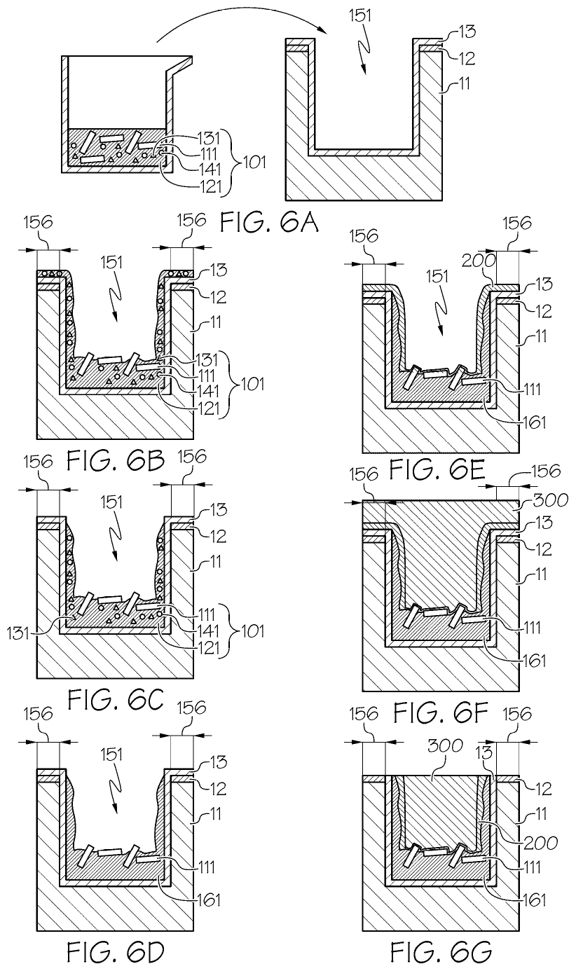

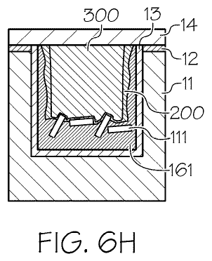

In embodiments, the sacrificial polymer composition of the polymer solution may further include a photo-initiator and a crosslinking agent to add a photoresist function to the sacrificial polymer composition. The photoresist function of the sacrificial polymer composition may allow selective removal of the coated polymer layer comprising the graphene nanosheets, the rGO nanosheets, or both from the field area. Referring back to FIG. 1 and now to FIG. 6A, the method 100 begins at step 110 with providing a polymer solution 101. The polymer solution 101 may include the at least one of the graphene nanosheets and the rGO nanosheets 111, the solvent 121, the sacrificial polymer composition 132, and the metal nanoparticles 141. The sacrificial polymer composition 132 may include the sacrificial polymer described in Methods A and B and further include a photo-initiator and a crosslinking agent.

In some embodiments, the photo-initiator may be selected from the group consisting of azobisisobutyronitrile, benzoyl peroxide, camphorquinone, benzophenone, 2-phenylacetophenone, derivatives of phenylacetophenone, such as 2,2-dimethoxy-2-phenylacetophenone, and combinations thereof. In some embodiments, the crosslinking agent may be selected from the group consisting of multifunctional acrylates, multifunctional methacrylates, and both. Multifunctional acrylates and multifunctional methacrylates may be selected from the group consisting of trimethylolpropane triacrylate, trimethylolpropane trimethacrylate, pentaerythritol triacrylate, pentaerythritol tetraacrylate, dipentaerythritol pentaacrylate, 1,6-hexanediol diacrylate, polyethylene glycol diacrylate, and combinations thereof.

Still referring to FIGS. 1 and 6A, the method continues a step 120 at step 120 where a dielectric material is provided. As shown in FIG. 6A, the dielectric material 11 may be the same or similar to the dielectric material shown in FIG. 4A with respect to Method B. The polymer solution 101 including the at least one of the graphene nanosheets and the rGO nanosheets 111, the solvent 121, the sacrificial polymer composition 132, and the metal nanoparticles 141 may be provided and applied onto the dielectric material 11 in a spin-coating step 130.

Referring back FIG. 1, and now to FIG. 6B, the method 100 continues at step 130 where the polymer solution 101 on the dielectric material 11 is spin coated to form a dispersion in the trench 151 as shown in FIG. 4B. The polymer solution 101 including the at least one of the graphene nanosheets and the rGO nanosheets 111, the solvent 121, the sacrificial polymer composition 132, and the metal nanoparticles 141 may be provided and applied onto the dielectric material 11, 21 in a spin-coating step 130.

Referring back FIG. 1, and now to FIG. 6C, the method 100 continues at step 135 where the polymer coating layer (spin-coated polymer solution) is exposed with the dielectric material 11 to an irradiation source through a photomask. The irradiation source may be selected from the group consisting of a UV light, electron beam, ⋅-irradiation, and combinations thereof. The photomask may have its masked areas overlapping with the field area 156. The polymer coating layer (dispersion) in the trench areas may be crosslinked and the polymer coating layer in the field area 156 may remain un-crosslinked after step 135.

Referring back FIG. 1, and now to FIG. 6D, the method 100 continues at step 137 where the irradiated polymer coating layer (spin-coated polymer solution) is developed by a solvent, then used to remove un-crosslinked polymer coating layer in the field area 156. In some embodiments, the solvent used for developing step 137 may be a good solvent of the sacrificial polymer. The solvent may be the same as or different from the solvent used for making the polymer solution.

Referring back FIG. 1, and now to FIG. 6D, the method 100 continues at step 140 where the dielectric material 11 is baked such that the sacrificial polymer 131 (shown in FIG. 6C) and the residual solvent may be removed to form an exposed surface of the electrically conductive composition. As shown in FIG. 6D, step 140 of Method C may be the same as or similar to step 140 shown in FIG. 4C and described above with respect to Method B.

Referring back to FIG. 1, in some embodiments, the method 100 may optionally continue at step 145 where the rGO nanosheets are reduced to the graphene nanosheets through an annealing step. In some embodiments, the oxygen content of the rGO nanosheets, which is normally between 10 wt % and 20 wt %, may be reduced to less than or equal to 3 wt % in order to convert rGO to the graphene nanosheets through an annealing step. The reducing step 145 may improve the electrical performance of the electrically conductive composition comprising the rGO nanosheets. In some embodiments, the rGO nanosheets may be converted to the graphene nanosheets through an annealing step in the presence of a reducing agent. The reducing agent may comprise hydrogen.

Referring back to FIG. 1, in some embodiments, the method 100 may optional continue at step 150 where the steps 130, 140, and 145 may be repeated until the at least one of the graphene nanosheets and the rGO nanosheets, and the metal nanoparticles 141 fill the depth of the trench 151 as shown in FIG. 6D. By repeating steps 130, 140, and 145, the amount of the electroplated copper composition may be reduced. In some embodiments, step 130 may be repeated one or more times prior to proceeding to step 140 or step 140 and 145. In some embodiments, steps 130 and 140 may be repeated one or more times. In some embodiments, all of steps 130, 140, and 145 may be repeated one or more times,

Referring back to FIG. 1 and now to FIG. 6E, the method 100 continues at step 160 where a metal seeding layer 200 is sputtered to the exposed surface of the electrically conductive composition. As shown in FIG. 6E, step 160 of Method C may be the same as or similar to step 160 shown in FIG. 4F and described above with respect to Method B.

Referring back to FIG. 1 and now to FIG. 6F, the method 100 continues at step 170 where a layer of a copper composition 300 is electroplated to the metal seeding layer 200. As shown in FIG. 6F, step 170 of Method C may be the same as or similar to step 170 shown in FIG. 4E and described above with respect to Method B.

Referring back to FIG. 1 and now to FIG. 6G, the method 100 continues at step 180 where a chemical mechanical polishing is performed to the layer of a copper composition 300. As shown in FIG. 6G, step 180 of Method C may be the same as or similar to step 180 shown in FIG. 4F and described above with respect to Method B.

Still Referring now to FIG. 6H, another dielectric passivation layer 14, 25 may be provided in the same or a similar manner as shown in FIG. 4G and described above with respect to Method B.

### Interconnect Structure

In embodiments, interconnect structure may be produced by at least one of Method A, Method B, and Method C. By referring to FIGS. 2G, 4G, and 6H, the interconnect structure may be a single layer interconnect structure having the trench 151. By referring to FIGS. 3G and 5G, the interconnect structure may be a dual-damascene interconnect structure having the trench 151 and the via 152. The conductive composition filled in the trench 151 and the via 152 is heterogeneous in that the graphene nanosheet fillers are dispersed in a continuous copper matrix of the trench and via.

The interconnect structure may be used in an integrated circuit (IC).

It will be apparent that modifications and variations are possible without departing from the scope of the disclosure defined in the appended claims. More specifically, although some aspects of the present disclosure are identified herein as preferred or particularly advantageous, it is contemplated that the present disclosure is not necessarily limited to these aspects.

1. A method of forming an interconnect structure, the method comprising:
(i) providing a polymer solution comprising:
an electrically conductive composition comprising at least one of graphene nanosheets and reduced graphene oxide (rGO) nanosheets;
a sacrificial polymer; and
a solvent;
(ii) providing a dielectric material, wherein the dielectric material includes a trench formed into a surface of the dielectric material;
(iii) spin coating the polymer solution on the dielectric material to form a dispersion in the trench of the electrically conductive composition within the sacrificial polymer;
(iv) baking the dielectric material such that the sacrificial polymer is removed to form an exposed surface of the electrically conductive composition;
(v) optionally reducing the rGO nanosheets to the graphene nanosheets through an annealing step where the rGO nanosheets included in the electrically conductive composition are reduced to graphene nanosheets;
(vi) sputtering a metal seeding layer to the exposed surface of the electrically conductive composition;
(vii) electroplating a layer of a copper composition to the metal seeding layer; and
(viii) performing a chemical mechanical polishing to the layer of the copper composition.

2. The method of forming the interconnect structure of claim 1, wherein the electrically conductive composition further comprises metal nanoparticles.

3. The method of forming the interconnect structure of claim 2, wherein the step of baking the dielectric material sinters the metal nanoparticles to form a continuous metal phase.

4. The method of forming the interconnect structure of claim 3, wherein the at least one of the graphene nanosheets and the rGO nanosheets are partially repelled by the continuous metal phase.

5. The method of forming the interconnect structure of claim 1, wherein the sacrificial polymer is polar.

6. The method of forming the interconnect structure of claim 1, wherein the sacrificial polymer is selected from the group consisting of polypropylene carbonate (PPC), polymethyl methacrylate (PMMA), poly(phthalaldehyde) including cyclic poly(phthalaldehyde), polylactides, polyhydroxyalkonoates, and combinations thereof.

7. The method of forming the interconnect structure of claim 1, wherein the solvent includes one or more of cyrene, triacetin, butyl lactate, cyclic aliphatic ketones, benzonitrile, N,N-dimethylacetamide, morpholine, N-methyl-2-pyrrolidone (NMP), and dimethylformamide (DMF).

8. The method of forming the interconnect structure of claim 1, wherein the at least one of the graphene nanosheets and the rGO nanosheets have been prepared from an expanded graphite material which was dispersed and exfoliated in a polar solvent.

9. The method of forming the interconnect structure of claim 1, wherein the at least one of the graphene nanosheets and the rGO nanosheets have an average lateral dimension less than or equal to 1000 nanometers and average thickness less than or equal to 10 nm.

10. The method of forming the interconnect structure of claim 1, wherein the metal nanoparticles are selected from the group consisting of copper, cobalt, ruthenium, nickel, titanium, aluminum, silver, gold, tungsten, platinum, palladium, and combinations thereof.

11. The method of forming the interconnect structure of claim 1, wherein the electrically conductive composition is free of metal nanoparticles.

12. The method of forming the interconnect structure of claim 1, wherein the metal nanoparticles have an average diameter less than 10 nm.

13. The method of forming the interconnect structure of claim 1, wherein the metal seeding layer is selected from the group consisting of copper, a copper alloy, and both.

14. The method of forming the interconnect structure of claim 1, wherein the copper composition is selected from the group consisting of copper, a predominantly copper alloy, and both.

15. The method of forming the interconnect structure of claim 1, wherein the step of performing the chemical mechanical polishing to the layer of a copper composition oxidizes a portion of copper in the layer of the copper composition; and the method further comprises a step to reduce the oxidized copper.

16. The method of forming the interconnect structure of claim 1, wherein the at least one of the graphene nanosheets and the rGO nanosheets are fillers at least partially imbedded in a copper matrix.

17. The method of forming the interconnect structure of claim 1, wherein the polymer solution further comprises a photo-initiator and a crosslinking agent.

18. The method of forming the interconnect structure of claim 17, further comprising:
exposing the spin-coated polymer solution to an irradiation source through a photomask; and
developing the irradiated spin-coated polymer solution.

19. An interconnect structure produced by the method of claim 1.
